(19) United States
(12) Patent Application Publication
(10) Pub. No.: US 2026/0117569 A1
(43) Pub. Date: Apr. 30, 2026

(54) HANDLE AND SLIDING RAIL ASSEMBLY WITH THE HANDLE

(71) Applicant: Nan Juen International Co., Ltd., Taoyuan City (TW)

(72) Inventor: Fu-Tien CHANG, Taoyuan City (TW)

(21) Appl. No.: 19/357,111

(22) Filed: Oct. 14, 2025

(30) Foreign Application Priority Data
Oct. 30, 2024 (TW) 113141922

(51) Int. Cl. E05C 1/12; A47B 88/473; A47B 88/483; A47B 95/02; H05K 7/14

(52) U.S. Cl. CPC E05C 1/12; A47B 88/473; A47B 95/02; H05K 7/1415; H05K 7/1489; A47B 88/483; A47B 2095/024

(57) ABSTRACT

A handle-equipped sliding rail assembly includes a handle body, a buckle having a front part located inside the handle body and a locking means located at the front end and disposed outside the handle body, and a switching member connected to the handle body and the buckle and movable relative to the handle body and the buckle between a first state where the switching member drives the buckle toward a first position and the locking means extends along with the buckle out of the handle body, and a second state where the switching member drives the buckle toward a second position and the locking means retracts along with the buckle into the inside of the handle body.

### BACKGROUND OF THE INVENTION

### 1. Field of the Invention

The present invention relates to a handle and a slide rail assembly with the handle, which uses the handle to lock or unlock the slide rail assembly and is combined with a server chassis or drawer, and can also be used in servers or furniture.

### 2. Description of the Related Art

With the maturation and development of the computer industry and cloud technology, the demand for electronic data access is increasing, especially in artificial intelligence (AI), such as ChatGPT. To meet the large-scale information access needs, the current server equipment structure is to set up multiple server chassis within a server rack. The server chassis and the server rack are connected by a slide rail structure. For example, a first slide rail is provided on each side of the server chassis, a second slide rail is provided on each side of the server rack relative to the first slide rail, and a longitudinal handle is fixed to the front end of the first slide rail. Therefore, the operator can use the longitudinal handle to drive the first slide rail so that the first slide rail is displaced on the second slide rail.

### SUMMARY OF THE INVENTION

The main object of the present invention is to provide a handle and its associated rail assembly, wherein the handle structure is independent of the rail member, facilitating operator installation and removal of the handle from the rail member. Furthermore, the handle can be mounted laterally on the inner side of the rail member, allowing the operator to apply force to the handle to displace the rail member.

Another object of the present invention is to provide a handle and its associated rail assembly, wherein the switching member of the handle faces the operator so that the operator can switch the lock state or unlock state of the buckle of the handle.

Still another object of the present invention is to provide a handle and its associated rail assembly, wherein the buckle of the handle is slid in a straight line to perform locking or unlocking, making it intuitive for the operator and avoiding complicated operations.

Still another object of the present invention is to provide a handle and its associated rail assembly, wherein when the buckle is in the unlocked state, the front end of the locking means of the buckle is reserved for the opening of the rail member, so that when the buckle is in the locked state, the locking means of the buckle does not need to be repositioned to the opening of the rail member, thereby preventing from causing failure when the operator uses the locking means of the buckle.

To achieve the above objects, the present invention provides a handle, which comprises a handle body, a buckle having a front part located inside the handle body and a locking means located at the front end and disposed outside the handle body, and a switching member connected to the handle body and the buckle and movable relative to the handle body and the buckle between a first state where the switching member drives the buckle toward a first position and the locking means extends along with the buckle out of the handle body, and a second state where the switching member drives the buckle toward a second position and the locking means retracts along with the buckle into the inside of the handle body.

To achieve the above objects, the present invention provides a handle-equipped sliding rail assembly, which comprises a handle body, a buckle having a front part located inside the handle body and a locking means located at the front end and disposed outside the handle body, a switching member connected to the handle body and the buckle and movable relative to the handle body and the buckle between a first state where the switching member drives the buckle toward a first position and the locking means extends along with the buckle out of the handle body, and a second state where the switching member drives the buckle toward a second position and the locking means retracts along with the buckle into the inside of the handle body, and a rail member comprising an opening relative to the locking means for allowing said locking means to extend out of the opening of the rail member or to retract into the opening of the rail member.

According to the aforementioned feature, when the locking means retracts within the opening, the front end of the locking means is positioned within the opening.

According to the aforementioned features, the handle body has a first connecting portion extended therefrom and connected to the rail member.

According to the aforementioned features, the handle body has a second connecting portion extend therefrom and connected to a carrier.

By means of the above technical means, the handle structure is separated from the rail member so that the operator can install or remove the handle from the rail member, and the handle can be installed laterally on the inner side of the rail member so that the operator can apply force to the handle to move the rail member. The switching member of the handle faces the operator so that the operator can switch the lock state or unlock state of the buckle of the handle. The buckle of the handle can be locked or unlocked by a linear movement, so that the operator can use it intuitively without complicated operations. Furthermore, when the buckle is in the unlocked state, the front end of the buckle's locking means is positioned toward the opening of the rail member, so that when the buckle is locked, the buckle's locking means does not need to be repositioned toward the opening of the rail member, thereby preventing from causing failure when the operator uses the locking means of the buckle.

### BRIEF DESCRIPTION OF THE DRAWINGS

FIG. 1 is an exploded three-dimensional external view of the handle of the present invention.

FIG. 2 is a three-dimensional external view of the handle of the present invention in the locked state.

FIG. 4 is an enlarged view of Part 4 in FIG. 3.

FIG. 5 is a side view of the handle of the present invention in the locked state.

FIG. 6 is a three-dimensional external view of the handle of the present invention in the unlocked state.

FIG. 7 is a front view of the handle of the present invention in the unlocked state.

FIG. 8 is an enlarged view of Part 8 in FIG. 7.

FIG. 9 is a side view of the handle of the present invention in the unlocked state.

FIG. 10 is a schematic diagram of the guide portion of the switching member of the present invention.

FIG. 11 is a three-dimensional external view of the handle of the present invention with the guide portion of the switching member being in a locked state.

FIG. 12 is a front view of the guide portion of the handle of the present invention, wherein the guide portion of the switching member is changed and in a locked state.

FIG. 13 is an enlarged view of Part 13A in FIG. 12.

FIG. 14 is a side view of the guide portion of the handle of the present invention, wherein the switching member is changed in the locked state.

FIG. 15 is a three-dimensional external view of the combination of the guide portion of the handle of the present invention with the switching member in the unlocked state.

FIG. 16 is a front view of the guide portion of the switching member of the handle-designed of the present invention in the unlocked state.

FIG. 17 is a schematic diagram of Part 17 in FIG. 16.

FIG. 18 is a side view of the guide portion of the switching member of the handle-designed of the present invention in the unlocked state.

FIG. 19 is an enlarged view of the handle and rail member of the present invention.

FIG. 20 is a schematic diagram of the combination of the handle and the rail member of the present invention.

FIG. 21 is a schematic diagram of the present invention, showing the locking means retracted from the middle frame and the outer frame.

FIG. 22 is a schematic diagram of the decomposition of the carrier and the rail member and the handle of the present invention.

FIG. 23 is a schematic diagram of the combination of the carrier and the rail member and the handle of the present invention.

FIG. 24 is a schematic diagram of the handle of the present invention in the rail member unlocked state.

FIG. 25 is a schematic diagram of the handle of the present invention driving the rail member and linking the carrier.

### DETAILED DESCRIPTION OF THE PREFERRED EMBODIMENT

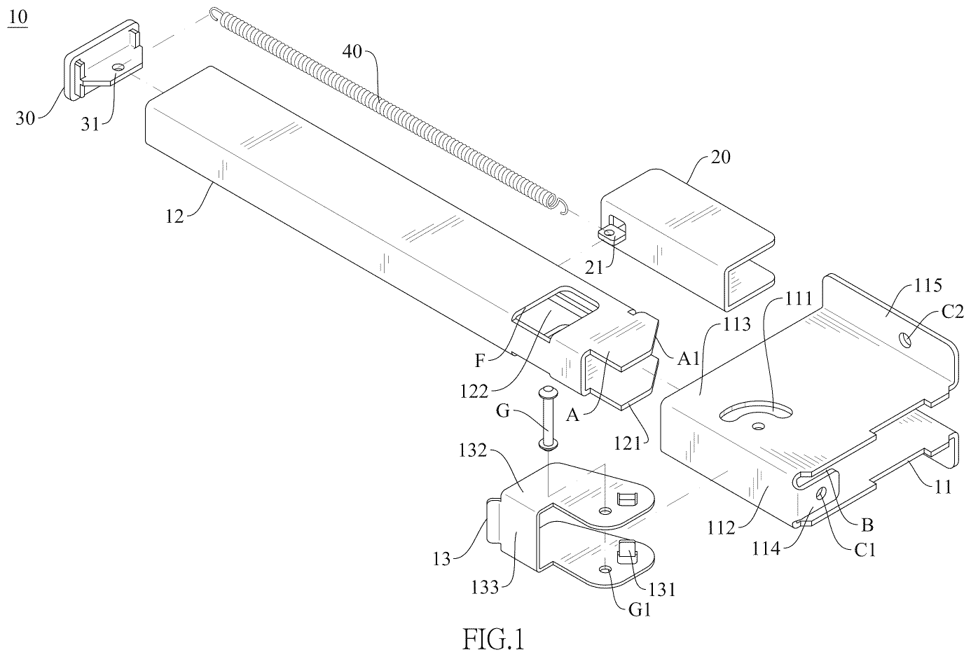

Please refer to FIGS. 1 to 9. The present invention provides a handle 10, comprising a handle body 11, a buckle 12, and a switching member 13.

In this embodiment, the handle body 11 is a U-shaped handle body, but the present invention is not limited thereto.

The buckle 12 has the front part thereof located inside the handle body 11, The front end of the front part of the buckle 12 is provided with a locking means 121, which is located outside the handle body 11. In this embodiment, the locking means is a pair of symmetrical locking pieces A, but it is not limited thereto.

The switching member 13 movably connects the handle body 11 and the buckle 12. When the switching member 13 is in a first state S1 and drives the buckle 12 toward a first position D1, the locking means 121 extends along with the buckle 12 out of the handle body 11. The first state S1 is a locked state. When the switching member 13 is in a second state S2 and drives the buckle 12 toward a second position D2, the locking means 121 retracts along with the buckle 12 into the inside of the handle body 11. The second state S2 is an unlocked state. In this embodiment, the handle body 11 has a guide hole 111, the buckle 12 has a guide opening 122, and the switching member 13 has a guide portion 131. The guide portion 131 is located between the guide hole 111 and the guide opening 122. When the guide portion 131 is displaced in the guide hole 111, the guide portion 131 drives the guide opening 122. To further explain, the guide hole 111 is arc-shaped and the guide opening 122 has a guide surface F. The guide hole 111 is provided with a first end point P1 and a second end point P2, but the present invention is not limited thereto.

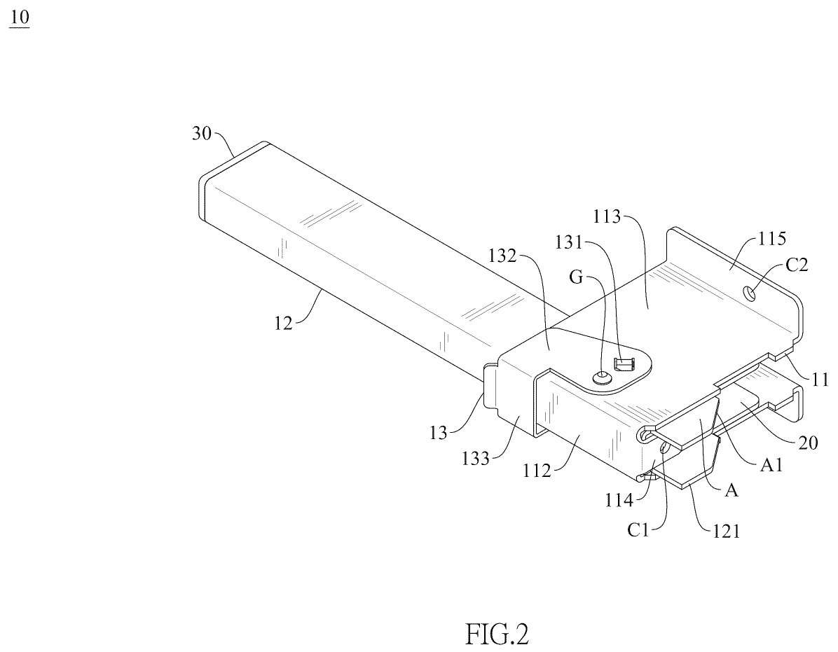

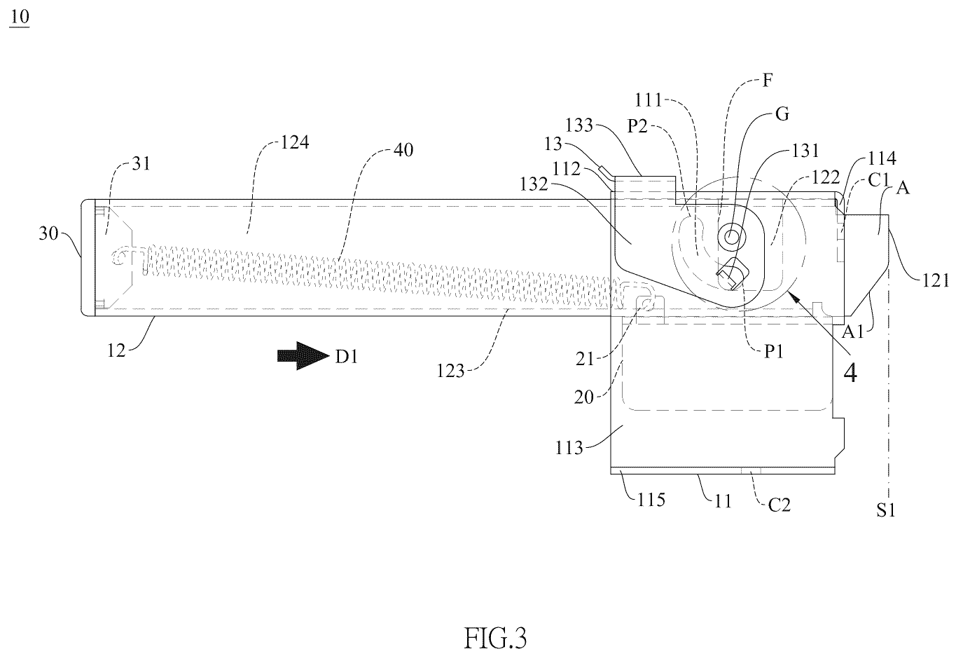

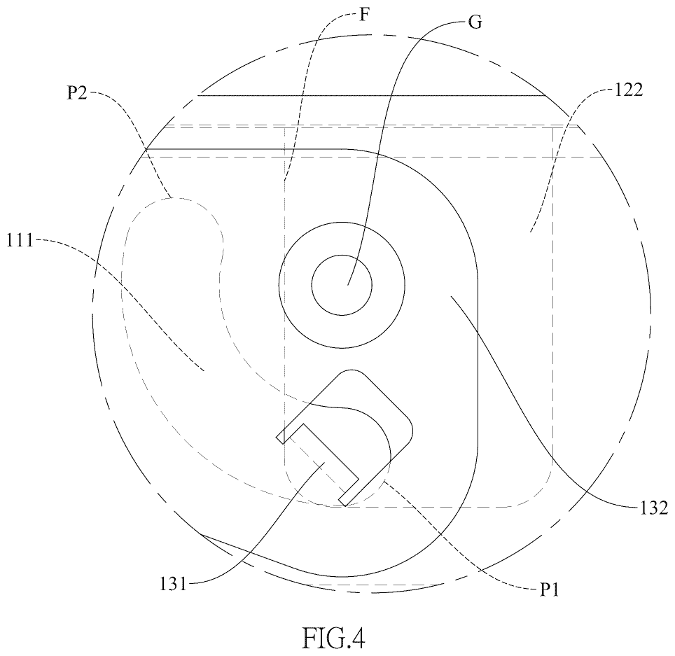

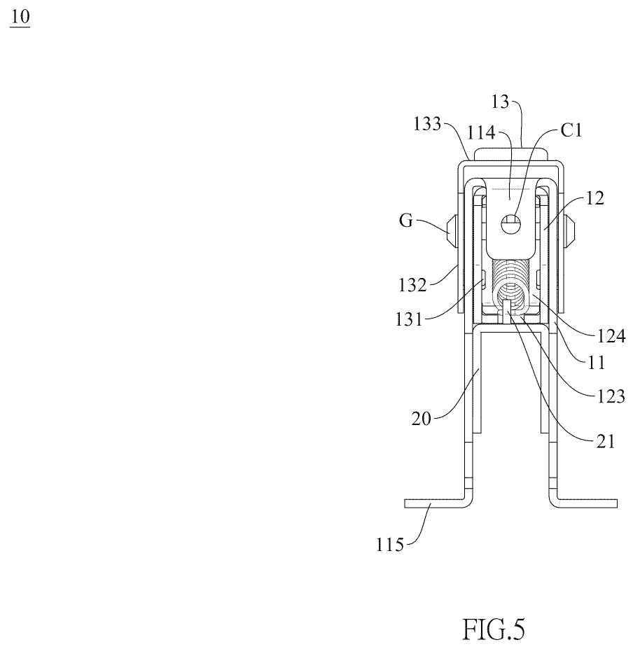

As shown in FIG. 2, FIG. 3, FIG. 4 and FIG. 5, the switching member 13 has a rotating portion 132 and an operating portion 133 extending from the rotating portion 132, and the handle body 11 has an abutting portion 112 and a supporting portion 113 extending from the abutting portion 112. The rotating portion 132 has an axis G and an axis hole G1 and is pivotally connected to the supporting portion 113 and the operating portion 133 relative to the abutting portion 112. When the switching member 13 is in the first state S1, the operating portion 133 is close to the abutting portion 112, and at this time, the guide portion 131 performs an arc-shaped displacement toward the first end point P1 of the guide hole 111.

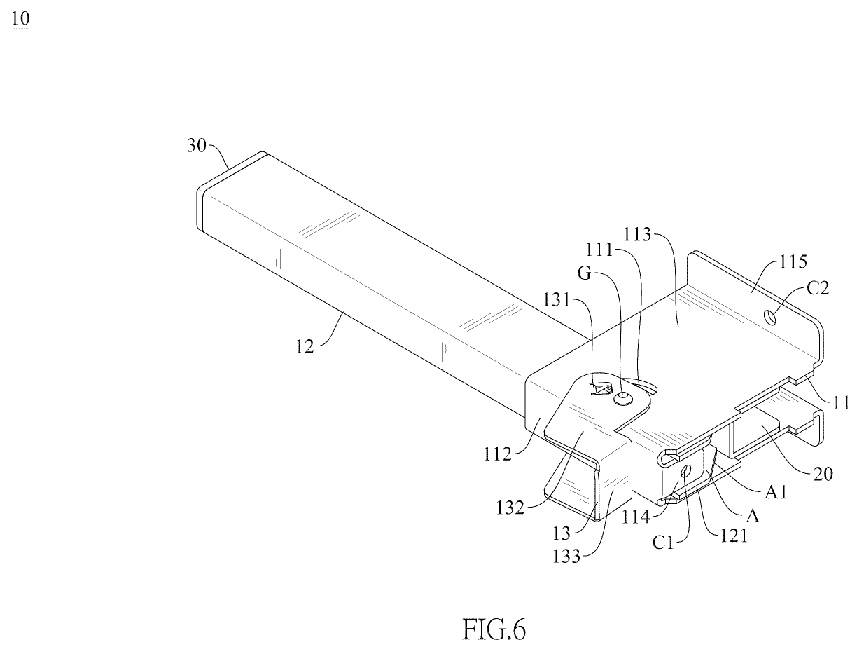

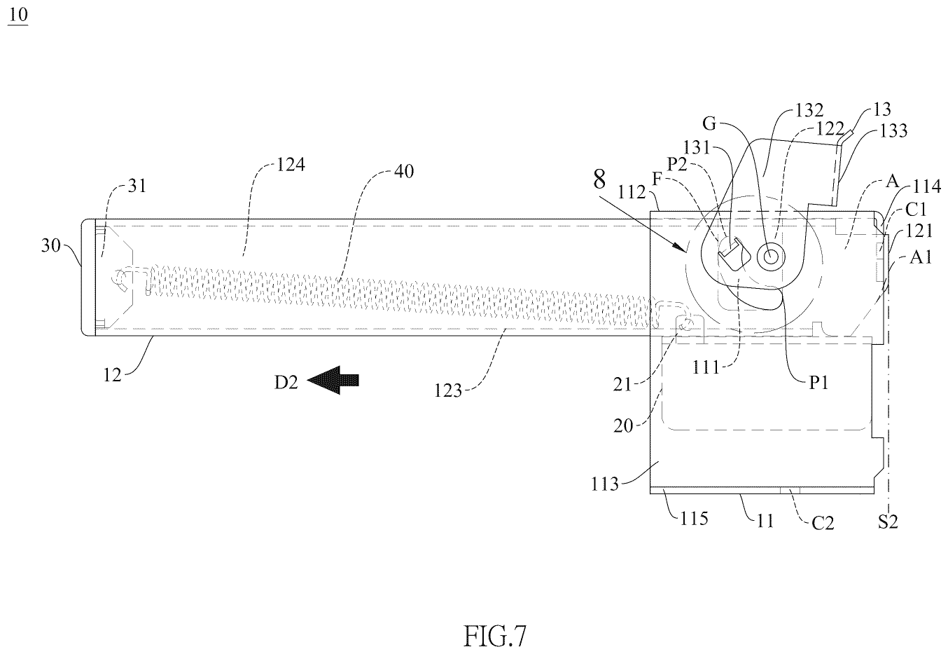

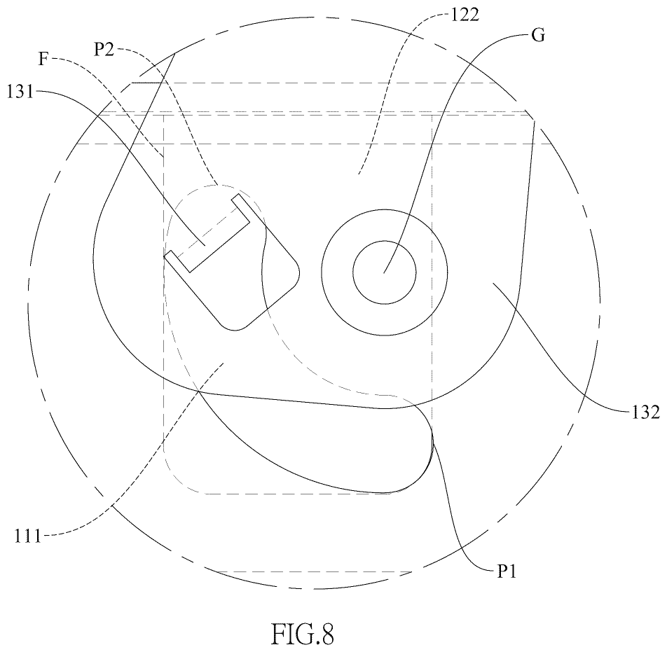

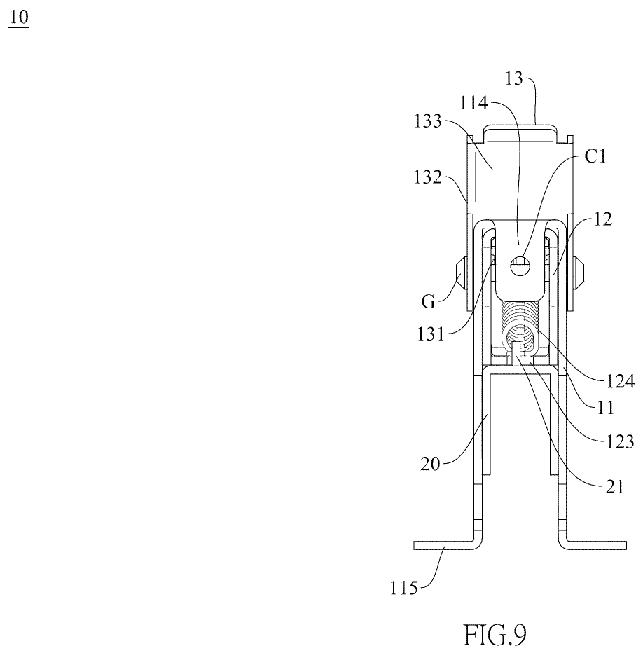

As shown in FIG. 6, FIG. 7, FIG. 8 and FIG. 9, when the switching member 13 is in the second state S2, the operating portion 133 is far away from the abutting portion 112. At the same time, when the guide portion 131 moves within the guide hole 111 along with the rotating portion 132, the guide portion 131 pushes the guide surface F, thereby driving the guide opening 122. At this time, the guide portion moves in an arc shape toward the second end point P2 of the guide hole 111.

In addition, a reinforcement member 20 may be included. The reinforcement member 20 is provided in the handle body 11 and is located on the side of the buckle 12. The reinforcement member 20 and the handle body 11 are fixed by mechanical elements such as screws and rivets. It may further comprises a cover 30 and an elastic member 40. The cover 30 is located at the rear of the buckle 12. One end of the elastic member 40 is connected to the reinforcement member 20, and the other end of the elastic member 40 is connected to the cover 30. In this embodiment, the buckle 12 has an accommodating space 124 with an opening 123, and the reinforcement member 20 has a first joint portion 21 and the cover 30 has a second joint portion 31. The first joint portion 21 extends to the accommodating space 124 through the opening 123, and the second joint portion 31 extends to the accommodating space 124 through the tail of the buckle 12. One end of the elastic member 40 is connected to the first joint portion 21 and the other end of the elastic member 40 is connected to the second joint portion 31, so that the elastic member 40 performs a buffering action in the accommodating space 124. The elastic member 40 may be a tension spring, but is not limited thereto.

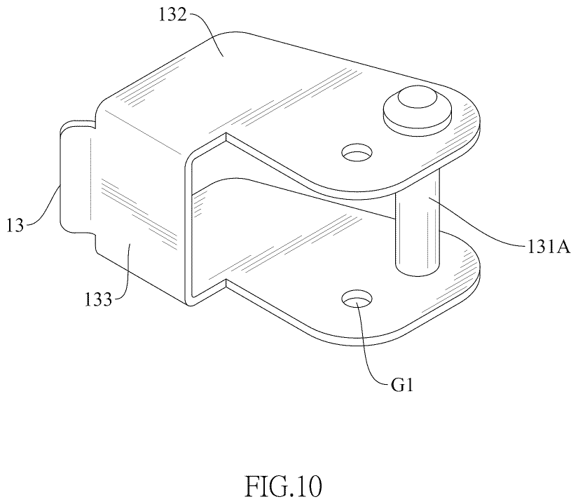

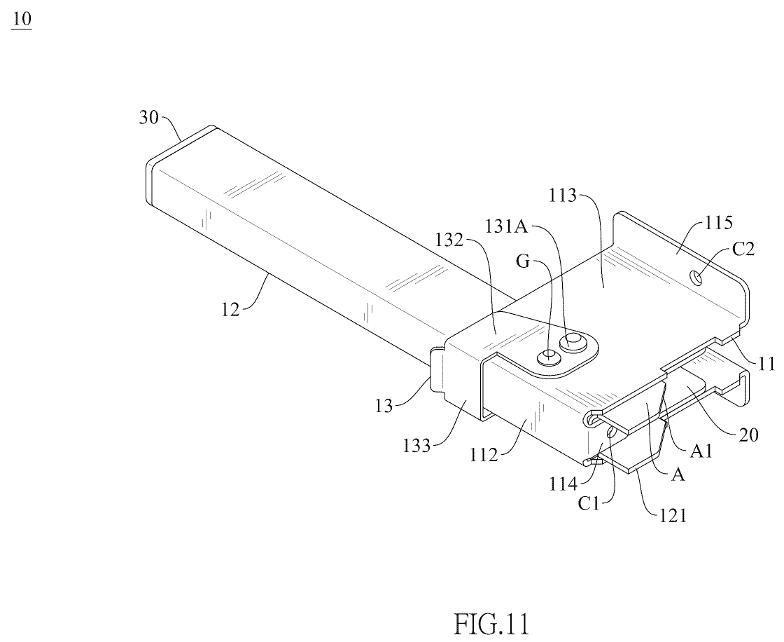

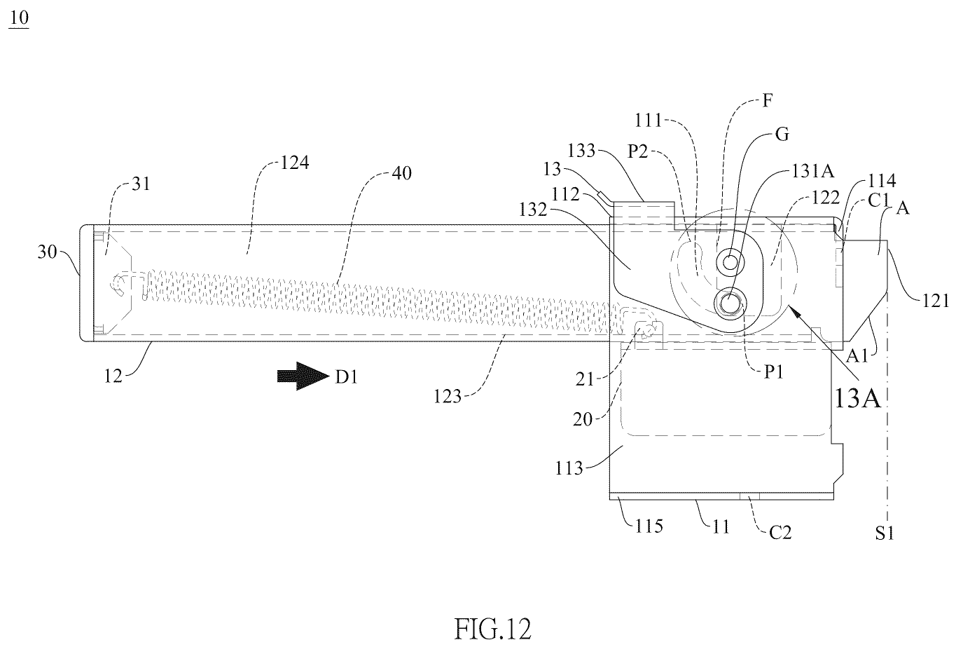

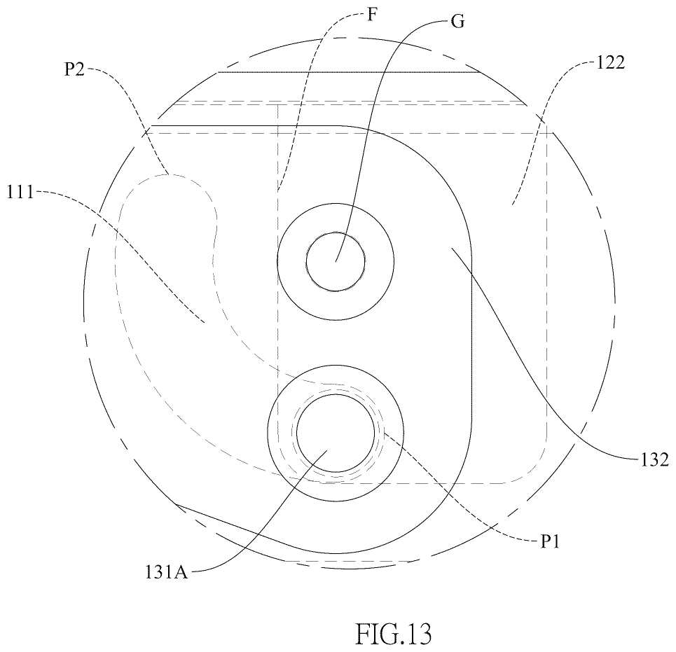

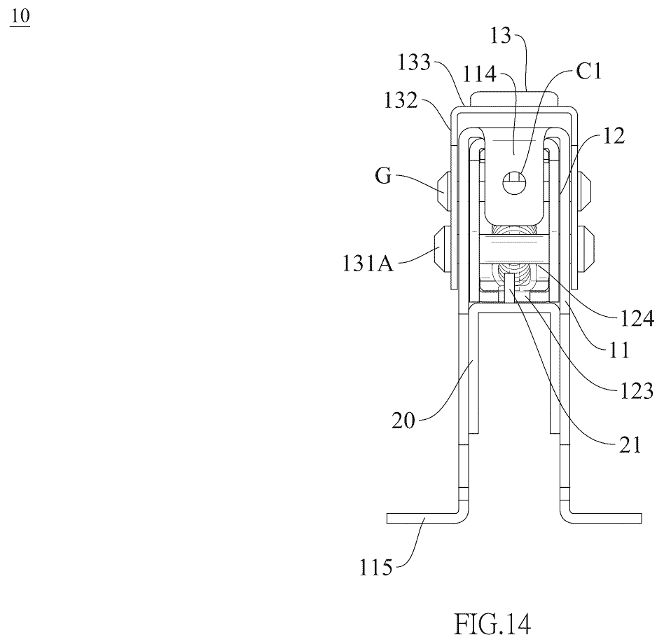

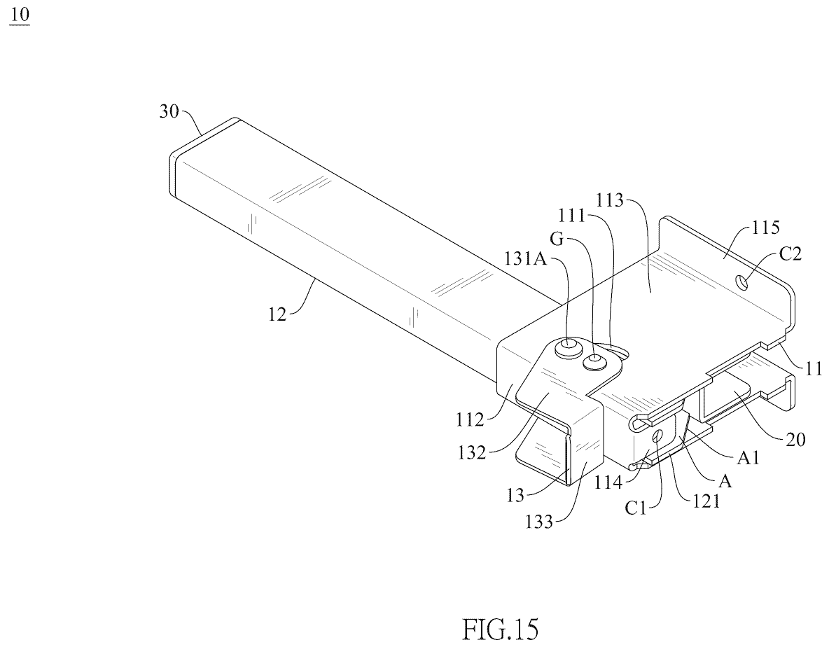

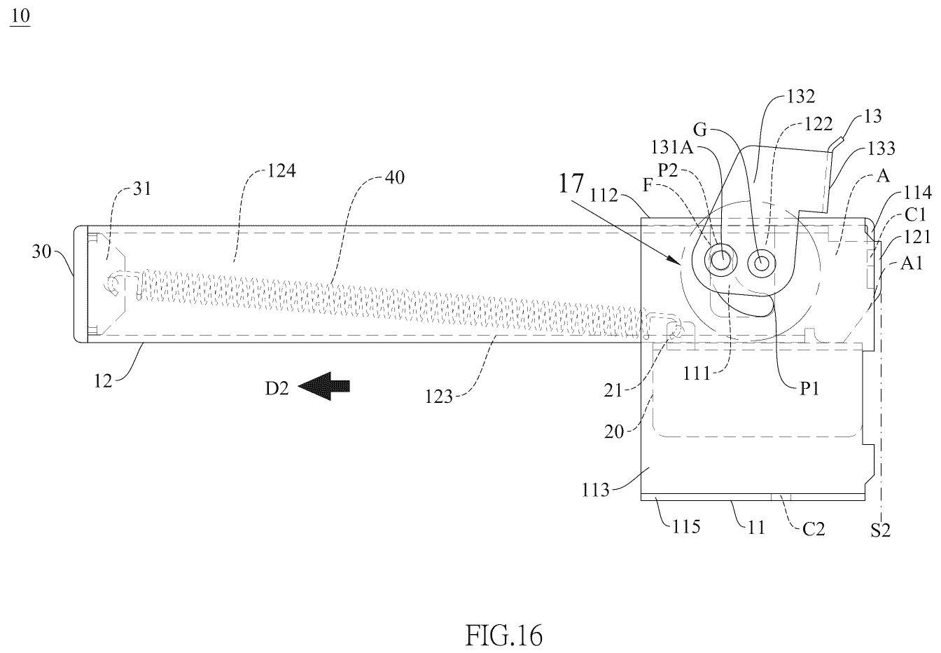

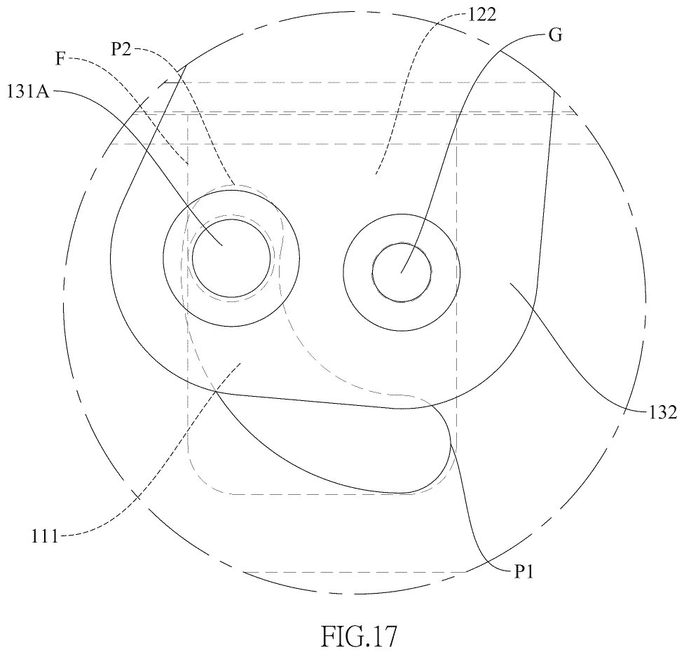

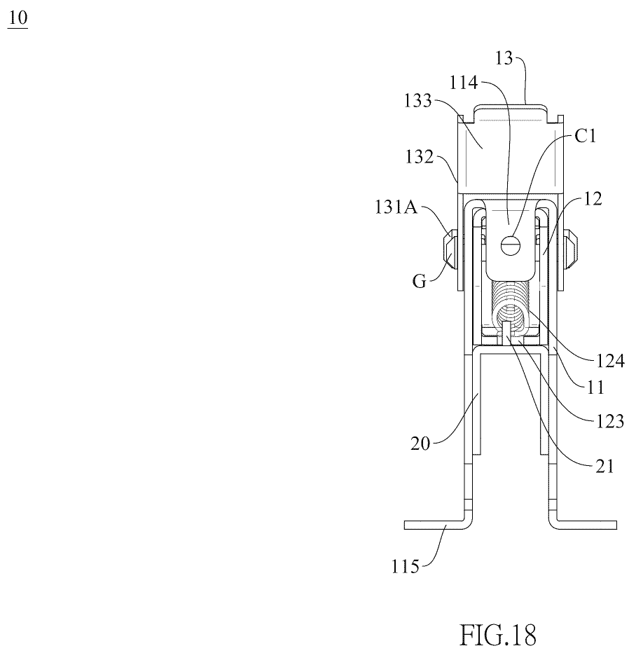

As above, the guide portion 131 is a bent sheet extending from the guide hole 111 to the guide opening 122, which is also the first embodiment. Next, as shown in FIGS. 10 to 18, the switching member 13 is only provided with one guide portion 131A, the guide portion 131A being a rivet passing through the switching member 13, which is a second embodiment. Therefore, the guide portion 131 of the first embodiment and the guide portion 131A of the second embodiment both have the function of pushing the guide surface F to drive the guide opening 122. In this way, FIG. 11 corresponds to FIG. 2, FIG. 12 corresponds to FIG. 3, FIG. 13 corresponds to FIG. 4, FIG. 14 corresponds to FIG. 5, FIG. 15 corresponds to FIG. 6, FIG. 16 corresponds to FIG. 7, FIG. 17 corresponds to FIG. 8, and FIG. 18 corresponds to FIG. 9 without further description.

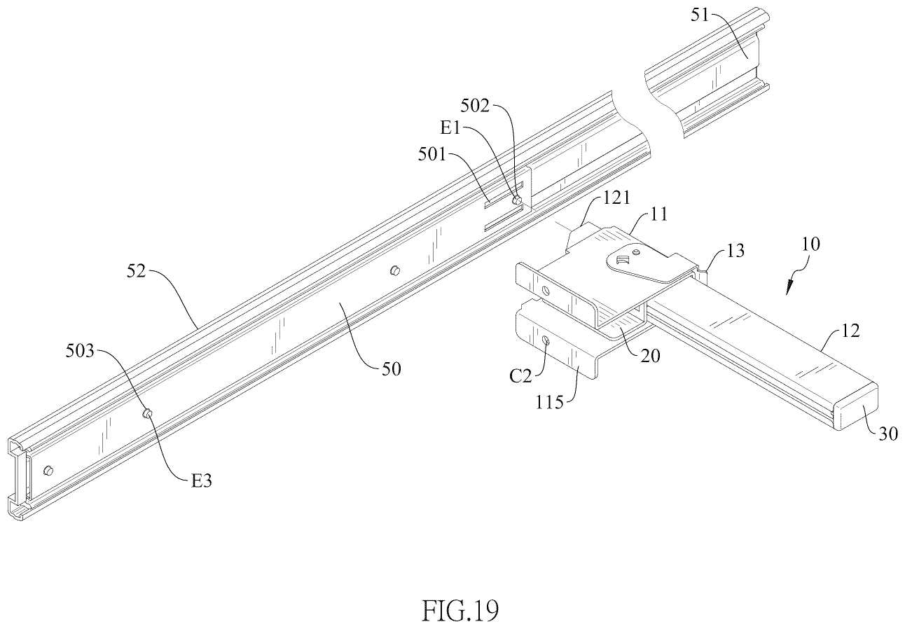

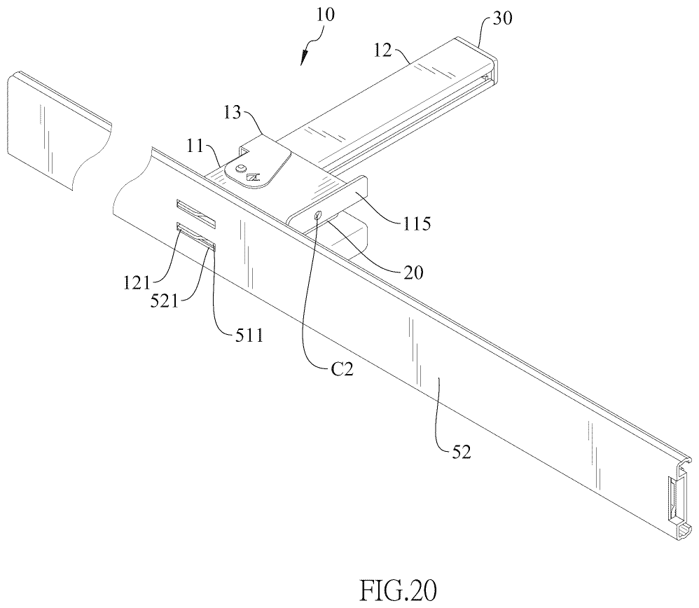

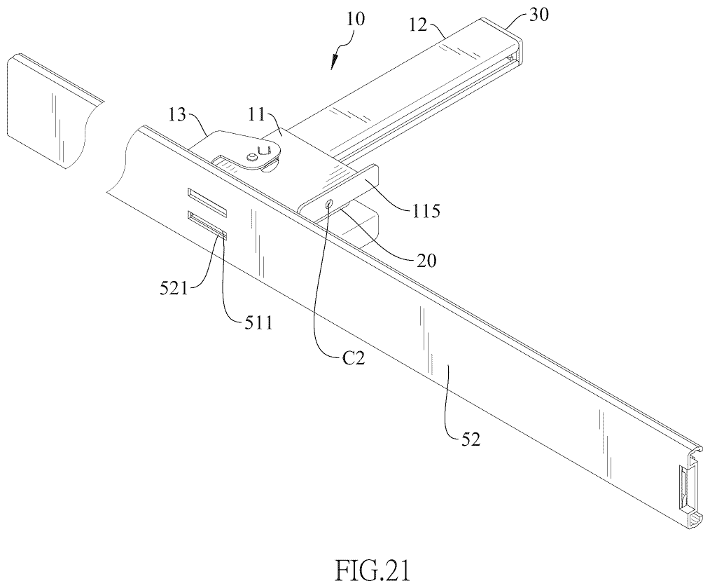

Please refer to FIG. 19, FIG. 20 and FIG. 21, a rail member 50 is provided with an opening 501, the opening 501 is relative to the locking means 121, the locking means 121 is extended or retracted in the opening 501. In this embodiment, a first connecting portion 114 extends from the front end of the handle body 11 to form two gaps B. Each locking piece A can extend or retract in one respective gap B. The first connecting portion 114 has a first connecting hole C1 and the rail member 50 has a first fixing hole 502 corresponding to the first connecting hole C1. The first connecting hole C1 is directly provided with an internal thread or additionally provided with a nut, and a first fixing member E1 with an external thread is passed through the first fixing hole 502 to the first connecting hole C1, so that the handle body 11 is fixed to the rail member 50. The locking pieces A each have a guide slope A1 to facilitate the extension or retraction of the locking means 121 in the opening 501, but is not limited thereto.

As mentioned above, the rail member 50 can be an inner frame, and the rail member 50 is slidably coupled to a middle frame 51, and the middle frame 51 is slidably coupled to an outer frame 52. The length of the rail member 50 is shorter than the length of the middle frame 51 and the length of the outer frame 52. The middle frame 51 has a first frame hole 511 and the outer frame 52 has a second frame hole 521. The opening 501 corresponds to the first frame hole 511 and the second frame hole 521 as the rail member 50 moves. Next, the locking means 121 extends and locks from the first frame hole 511 to the second frame hole 521, or retracts and moves from the first frame hole 511 to the second frame hole 521. When the locking means 121 is retracted within the opening 501, the front end of the locking means 121 is positioned within the opening 501. Therefore, when the locking means 121 is extended, the locking means 121 does not need to be repositioned within the opening 501.

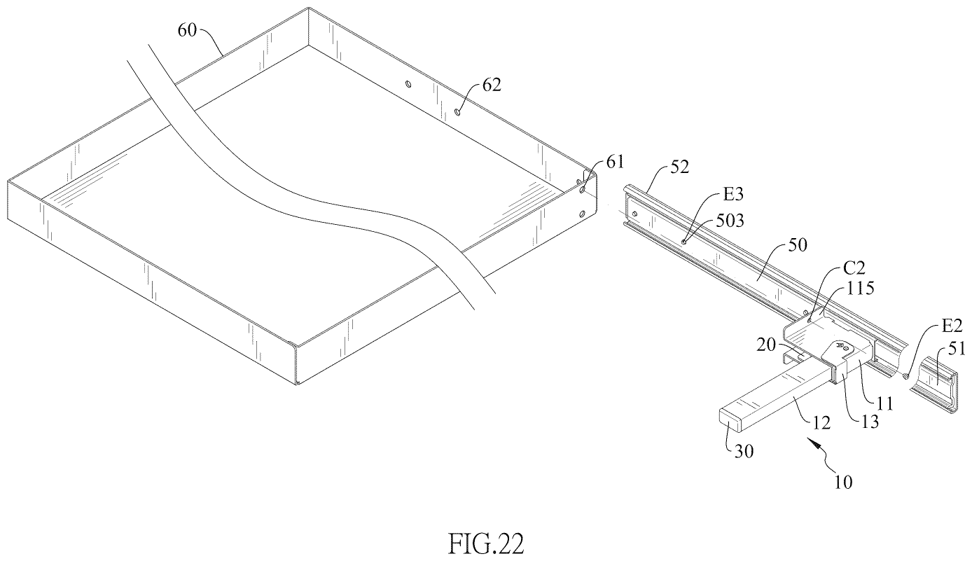

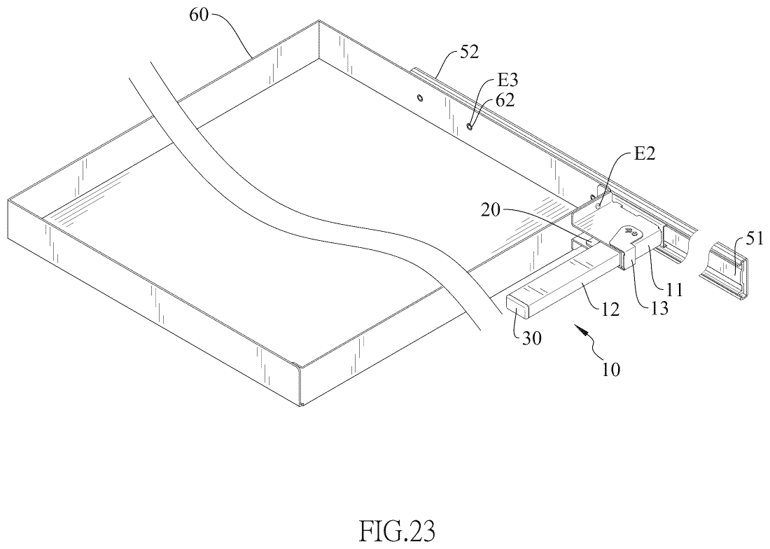

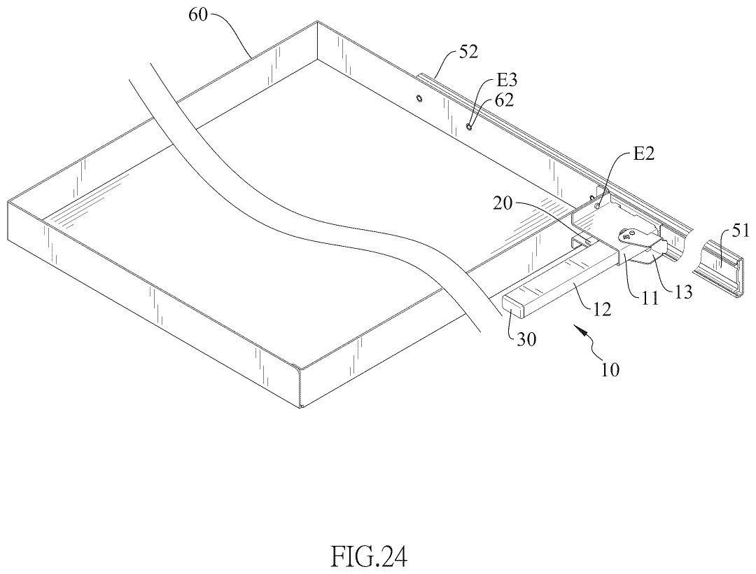

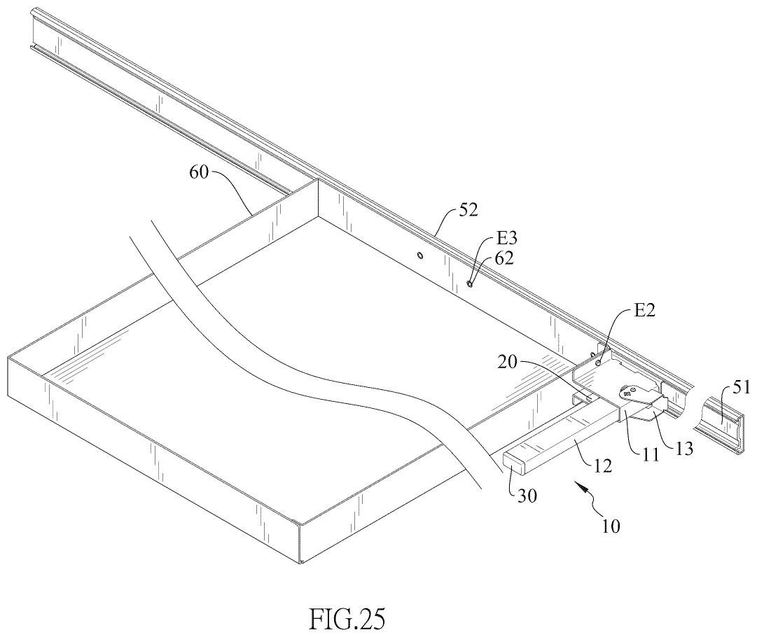

Referring again to FIGS. 22, 23, 24 and 25, a second connecting portion 115 extends from the side of the handle body 11, and the second connecting portion 115 is connected to a carrier 60. The second connecting portion 115 has a second connecting hole C2, and one side of the carrier 60 has a first hole 61. The first hole 61 corresponds to the second connecting hole C2. A second fixing member E2 is inserted through the second connecting hole C2 to the first hole 61, thereby fixing one side of the carrier 60 to the handle body 11. The rail member 50 is provided with a second fixing hole 503 and the other side of the carrier 60 is provided with a second hole 62. A third fixing member E3 is passed through the second fixing hole 503 to the second hole 62, so that the other side of the carrier 60 is fixed to the rail member 50. Therefore, after the handle 10 is unlocked in the rail member 50, the handle 10 drives the rail member 50 and the carrier 60. The carrier 60 can be a server chassis or a drawer, and can also be used in servers or furniture.

What the invention claimed is:

1. A handle, comprising:
a handle body;
a buckle having a front part thereof located inside said handle body, said buckle comprising a locking means located at a front end of the front part thereof and disposed outside said handle body; and
a switching member connected to said handle body and said buckle and movable relative to said handle body and said buckle between a first state where said switching member drives said buckle toward a first position and said locking means extends along with said buckle out of said handle body, and a second state where said switching member drives said buckle toward a second position and said locking means retracts along with said buckle into the inside of said handle body.

2. The handle as claimed in claim 1, wherein said handle body comprises a guide hole, said buckle comprises a guide opening, and said switching member comprises a guide portion located between said guide hole and said guide opening, wherein when said guide portion is displaced in said guide hole, said guide portion drives said guide opening to move.

3. The handle as claimed in claim 1, wherein said switching member comprises a rotating portion and an operating portion extending from said rotating portion, and said handle body comprises an abutting portion and a supporting portion extending from said abutting portion, said rotating portion being pivotally connected to said supporting portion and said operating portion being relative to said abutting portion so that. when said switching member is in said first state, said operating portion is close to said abutting portion, or when said switching member is in said second state, said operating portion is away from said abutting portion.

4. The handle as claimed in claim 3, wherein said rotating portion has an axis and an axis hole.

5. The handle as claimed in claim 3, wherein said handle body further comprises an arc-shaped guide hole formed therein and located on said supporting portion, said buckle further comprises a guide opening and said switching member further comprises a guide portion provided with a guide surface and located between said guide hole and said guide opening; when said guide portion moves in said guide hole along with said rotating portion, said guide portion pushes said guide surface and drives said guide opening to move.

6. The handle as claimed in claim 5, wherein said guide hole defines a first end point and a second end point, and said guide portion is displaced in an arc shape between said first end point of said guide hole and said second end point of said guide hole.

7. The handle as claimed in claim 1, wherein said handle body further comprises a first connecting portion extending from a front end thereof to form two gaps, and said locking means comprises two symmetrical locking pieces movable in and out of said two gaps respectively.

8. The handle as claimed in claim 7, wherein said locking pieces each comprise a guide slope.

9. The handle as claimed in claim 1, further comprising a reinforcement member located within said handle body and on one side of the buckle.

10. The handle as claimed in claim 9, further comprising a cover located at an opposing rear end of said buckle, and an elastic member with one end thereof connected to said reinforcement member and an opposite end thereof connected to said cover.

11. The handle as claimed in claim 10, wherein said buckle further comprises an accommodating space with an opening, said reinforcement member comprises a first joint portion extending through the opening of said accommodating space to the inside of said accommodating space, and said cover comprises a second joint portion extending through the rear end of said buckle to the inside of said accommodating space; said elastic member has one end thereof connected to said first joint portion and the other end thereof connected to said second joint portion.

12. A sliding rail assembly, comprising:
a handle body;
a buckle having a front part thereof located inside said handle body, said buckle comprising a locking means located at a front end of the front part thereof and disposed outside said handle body;
a switching member connected to said handle body and said buckle and movable relative to said handle body and said buckle between a first state where said switching member drives said buckle toward a first position and said locking means extends along with said buckle out of said handle body, and a second state where said switching member drives said buckle toward a second position and said locking means retracts along with said buckle into the inside of said handle body; and
a rail member, said rail member comprising an opening relative to said locking means for allowing said locking means to extend out of the opening of said rail member or to retract into the opening of said rail member.

13. The sliding rail assembly as claimed in claim 12, wherein when said locking means retracts into the opening of said rail member, said locking means has a front end thereof located within the opening of said rail member.

14. The sliding rail assembly as claimed in claim 12, wherein said handle body comprises a first connecting portion connected to said rail member.

15. The sliding rail assembly as claimed in claim 14, wherein said first connecting portion is provided with a first connecting hole; said rail member comprises a first fixing hole corresponding to said first connecting hole, and a first fixing member passed through said first fixing hole to said first connecting hole to fix said handle body to said rail member.

16. The sliding rail assembly as claimed in claim 12, wherein said handle body further comprises a second connecting portion connected to a carrier.

17. The sliding rail assembly as claimed in claim 16, wherein said carrier comprises a first hole on one side thereof and a second hole on an opposite side thereof; said handle body further comprises a second connecting hole located on said second connecting portion, and a second fixing member passed through said second connecting hole to said first hole to fix one side of said carrier to said handle body; said rail member comprises a second fixing hole, and a third fixing member passed through said second fixing hole to said second hole to fix the opposite side of said carrier to said rail member.

18. The sliding rail assembly as claimed in claim 12, further comprising a middle frame provided with a first frame hole and an outer frame provided with a second frame hole, wherein said rail member is an inner frame slidably coupled to said middle frame; said middle frame is slidably coupled to said outer frame; the length of said rail member is shorter than the length of said middle frame and the length of said outer frame; said opening of said rail member corresponds to said first frame hole and said second frame hole as said rail member moves, and subsequently, said locking means extends and locks to said first frame hole and said second frame hole, or retracts and moves away from said first frame hole and said second frame hole.
